(19) United States
(12) Patent Application Publication
(10) Pub. No.: US 2026/0252434 A1
(43) Pub. Date: Aug. 27, 2026

(54) INFORMATION PROCESSING METHOD, INFORMATION PROCESSING DEVICE, AND NON-TRANSITORY COMPUTER READABLE RECORDING MEDIUM

(71) Applicant: PANASONIC INTELLECTUAL PROPERTY MANAGEMENT CO., LTD., Osaka (JP)

(72) Inventors: Masahiro TAGUCHI, Osaka (JP); Yuki Hayashi, Osaka (JP)

(21) Appl. No.: 19/654,943

(22) Filed: Apr. 22, 2026

Related U.S. Application Data
(63) Continuation of application No. PCT/JP2024/032514, filed on Sep. 11, 2024.

(30) Foreign Application Priority Data
Oct. 26, 2023 (JP) 2023-184251

(51) Int. Cl. G06F 11/07

(52) U.S. Cl. CPC G06F 11/079; G06F 11/0778

(57) ABSTRACT

An information processing device displays a plurality of abnormal state items of a plurality of batteries in time series for each battery, and displays a plurality of state items of a battery in which an abnormality indicated by one abnormal state item has occurred when selection of the one abnormal state item among the plurality of abnormal state items is detected, in which the displaying of the plurality of state items includes displaying a plurality of pieces of history information corresponding to the plurality of state items in a first period before and after an abnormality occurrence time point at which an abnormality indicated by the one abnormal state item has occurred.

### FIELD OF INVENTION

The present disclosure relates to a technique of displaying a history information of a battery in which an abnormal value is detected.

### BACKGROUND ART

Patent Literature 1 discloses a battery degradation diagnosis system that displays history information such as internal resistance or charge capacity in a battery in which an abnormality has occurred in time series.

When analyzing the cause of the abnormality of the battery, the user needs to check not only the item determined to be abnormal but also other items.

However, in the above-described conventional technique, since the history information is displayed only for the item determined to be abnormal, there is a problem that a burden on the user is large in performing more detailed analysis.

Patent Literature 1: JP 2018-169161 A

### SUMMARY OF THE INVENTION

The present disclosure has been made to solve the above problems, and an object of the present disclosure is to provide a technique capable of reducing a burden on a user when analyzing a cause of abnormality of a battery in detail.

An information processing method according to an aspect of the present disclosure is an information processing method in a computer, including: acquiring, from battery log information of a plurality of batteries, state data of the plurality of batteries; displaying, based on the state data, a plurality of abnormal state items of the plurality of batteries in time series for each battery; and displaying a plurality of state items of a battery in which an abnormality indicated by one abnormal state item has occurred when selection of the one abnormal state item among the plurality of abnormal state items is detected, in which the displaying of the plurality of state items includes displaying a plurality of pieces of history information corresponding to the plurality of state items in a first period before and after an abnormality occurrence time point at which an abnormality indicated by the one abnormal state item has occurred.

According to the present disclosure, it is possible to reduce the burden on the user when the cause of the abnormality of the battery is analyzed in detail.

### BRIEF DESCRIPTION OF THE DRAWINGS

FIG. 1 is a diagram illustrating an overall configuration of a battery management system in a first embodiment of the present disclosure.

FIG. 2 is a sequence illustrating the battery management system in the first embodiment of the present disclosure.

FIG. 3 is a flowchart illustrating details of extraction processing of history information described in step S7 in FIG. 2.

FIG. 4 is a diagram illustrating an example of a first dashboard screen.

FIG. 5 is a diagram illustrating an example of a second dashboard screen.

FIG. 6 is a graph showing a temporal transition of history information of a pack current.

FIG. 7 is a flowchart illustrating details of extraction processing of history information in a third embodiment.

FIG. 8 is a diagram illustrating an example of a second dashboard screen in the third embodiment.

FIG. 9 is a graph showing a temporal transition of history information displayed on a second dashboard screen in a fourth embodiment.

FIG. 10 is a diagram illustrating an example of a second dashboard screen in a fifth embodiment.

### DETAILED DESCRIPTION

### Knowledge underlying present disclosure

As described above, when analyzing the cause of the abnormality of the battery, the user needs to check not only the item determined to be abnormal but also other items. For this purpose, it is conceivable to display history information of other items.

In order to analyze the cause of the abnormality of the battery, history information of the battery before and after the time when the abnormality has occurred is important. Therefore, when the history information of other items is displayed, the user cannot sufficiently analyze the cause of the abnormality of the battery unless the data at the abnormality occurrence time point is included.

In the technique of Patent Literature 1 described above, only the history information of the abnormal state item is displayed, and thus there is no idea of how to display the history information of other state items. Therefore, the technique of Patent Literature 1 described above is insufficient for reducing the burden on the user when the cause of the abnormality of the battery is analyzed in detail.

The present disclosure has been made in order to solve such a problem.

(1) An information processing method according to an aspect of the present disclosure is an information processing method in a computer, including: acquiring, from battery log information of a plurality of batteries, state data of the plurality of batteries; displaying, based on the state date, a plurality of abnormal state items of the plurality of batteries in time series for each battery; and displaying a plurality of state items of a battery in which an abnormality indicated by one abnormal state item has occurred when selection of the one abnormal state item among the plurality of abnormal state items is detected, in which the displaying of the plurality of state items includes displaying a plurality of pieces of history information corresponding to the plurality of state items in a first period before and after an abnormality occurrence time point at which an abnormality indicated by the one abnormal state item has occurred.

According to this configuration, when one abnormal state item is selected from among a plurality of abnormal state items, a plurality of pieces of history information corresponding to the plurality of state items is displayed. The plurality of pieces of history information to be displayed includes the first period before and after the abnormality occurrence time point. As a result, the user can analyze the cause of the abnormality of the battery in detail while checking the plurality of pieces of history information including the abnormality occurrence time point. Therefore, this configuration can reduce the burden on the user when the cause of the abnormality of the battery is analyzed in detail.

(2) In the information processing method according to (1), the displaying of the plurality of abnormal state items in time series for each battery may include displaying a reference index indicating the abnormality occurrence time point.

In this case, on the display screen in which a plurality of abnormal state items are displayed in time series for each battery, the user can easily confirm which point corresponds to one abnormal state item.

(3) In the information processing method according to (1) or (2), the displaying of the plurality of state items may include displaying a reference index indicating the abnormality occurrence time point in each of the plurality of pieces of history information.

The acquisition frequency of the history information varies depending on the plurality of state items. In this case, the plurality of pieces of history information may be displayed in different time ranges. Then, it becomes difficult for the user to grasp a time point at which the user should gaze at the plurality of pieces of history information. In addition, when the user inputs various operations in order to display the time point to be watched in the plurality of pieces of history information, the number of processing steps increases. In this configuration, a reference index indicating an abnormality occurrence time point is displayed for each of the plurality of pieces of history information. Therefore, the user can easily grasp which time point is the abnormality occurrence time point in the plurality of pieces of history information. As a result, the user can easily grasp the time point at which the user should gaze at the plurality of pieces of history information, and the burden in analyzing the cause of the abnormality of the battery is further reduced. In addition, the user does not need to input an unnecessary operation, and the processing steps of the computer spent on the operation can be reduced.

(4) In the information processing method according to any one of (1) to (3), the displaying of the plurality of state items may include specifying an abnormal value included in each of the plurality of pieces of history information based on the plurality of pieces of history information, and setting the first period such that the abnormal value is included.

According to this configuration, since the abnormal value included in the history information is displayed for the user, it is possible to further reduce the burden on the user when the cause of the abnormality of the battery is analyzed in detail.

(5) In the information processing method according to (4), the first period may include one or a plurality of unit periods in which an index of the abnormal value exceeds a threshold.

According to this configuration, since the history information of the period in which the index of the abnormal value exceeds the threshold is displayed, the user can intensively analyze the period in which the sign of the abnormality appears.

(6) In the information processing method according to (4), the displaying of the plurality of state items may include specifying a state item related to the one abnormal state item among the plurality of state items, and highlighting history information of a state item associated with the one abnormal state item.

According to this configuration, the user can quickly confirm the state item related to the one state item.

(7) In the information processing method according to (4), the displaying of the plurality of state items may include highlighting the abnormal value.

According to this configuration, since the abnormal value is highlighted, the user can quickly confirm the abnormal value included in the history information.

(8) In the information processing method according to any one of (1) to (7), the displaying of the plurality of state items may include specifying a first use period in which one battery is in a use state based on the plurality of pieces of history information of the one battery corresponding to the one abnormal state item, and setting the first period as the first use period.

In this case, the history information can be displayed while omitting a period that is not so important in analyzing the cause of the abnormality of the battery.

(9) In the information processing method according to (8), the first use period may include a plurality of second use periods in the use state of the one battery.

In this case, since the history information in the plurality of second use periods is displayed, the user can check the history information over a long period of time and perform more accurate analysis.

(10) In the information processing method according to any one of (1) to (9), the displaying of the plurality of state items may include specifying, based on the plurality of pieces of history information of one battery corresponding to the one abnormal state item, one cycle period of charging and discharging of the one battery including the abnormality occurrence time point, and setting the first period to the one cycle period.

In this case, since the transition of the history information in one cycle period of charging and discharging can be confirmed, the cause of the abnormality of the battery can be more accurately analyzed.

(11) In the information processing method according to any one of (1) to (10), the displaying of the plurality of state items may include displaying first history information that is history information of the one abnormal state item in the first period, and displaying second history information as history information of the one abnormal state item in a second period different from the first period in which a same abnormality as the abnormality indicated by the one abnormal state item has occurred, the second period having a same time width as the first period, in alignment with the first history information.

In this case, since the first history information and the second history information in which the same abnormality as the abnormality indicated by the one abnormal state item has occurred are displayed, the user can confirm the pattern of the history information for this abnormality. In addition, since the first history information and the second history information have the same time width, and both pieces of history information are displayed side by side, comparison between both pieces of history information is facilitated.

(12) In the information processing method according to (11), the first history information and the second history information may include history information of one battery corresponding to the one abnormal state item and history information of a battery different from the one battery.

In this case, the user can check the first history information and the second history information not only for one battery corresponding to one abnormal state item but also for other batteries.

(13) An information processing device according to another aspect of the present disclosure is an information processing device including a processor, in which the processor is configured to execute: acquiring, from battery log information of a plurality of batteries, state data of the plurality of batteries; displaying, based on the state data, a plurality of abnormal state items of the plurality of batteries in time series for each battery; and displaying a plurality of state items of a battery in which an abnormality indicated by one abnormal state item has occurred when selection of the one abnormal state item among the plurality of abnormal state items is detected, and the displaying of the plurality of state items includes displaying a plurality of pieces of history information corresponding to the plurality of state items in a first period before and after an abnormality occurrence time point at which an abnormality indicated by the one abnormal state item has occurred.

According to this configuration, it is possible to provide an information processing device capable of reducing the burden on the user when the cause of the abnormality of the battery is analyzed in detail.

(14) An information processing program according to another aspect of the present disclosure causes a computer to execute: acquiring, from battery log information of a plurality of batteries, state data of the plurality of batteries; displaying, based on the state data, a plurality of abnormal state items of the plurality of batteries in time series for each battery; and displaying a plurality of state items of a battery in which an abnormality indicated by one abnormal state item has occurred when selection of the one abnormal state item among the plurality of abnormal state items is detected, in which the displaying of the plurality of state items includes displaying a plurality of pieces of history information corresponding to the plurality of state items in a first period before and after an abnormality occurrence time point at which an abnormality indicated by the one abnormal state item has occurred.

According to this configuration, it is possible to provide an information processing program capable of reducing the burden on the user when the cause of the abnormality of the battery is analyzed in detail.

The present disclosure can be also implemented as an information system that is operated by such an information processing program. Further, it is needless to say that such a computer program can be distributed via a computer-readable non-transitory recording medium such as a CD-ROM or via a communication network such as the Internet.

Note that each of embodiments to be described below illustrates a specific example of the present disclosure. Numerical values, shapes, components, steps, order of steps, and the like of the embodiments below are merely examples, and are not intended to limit the present disclosure. Further, a component not described in an independent claim representing a highest concept among components in the embodiments below is described as an optional component. Further, in all the embodiments, content of each of the embodiments can be combined.

### First embodiment

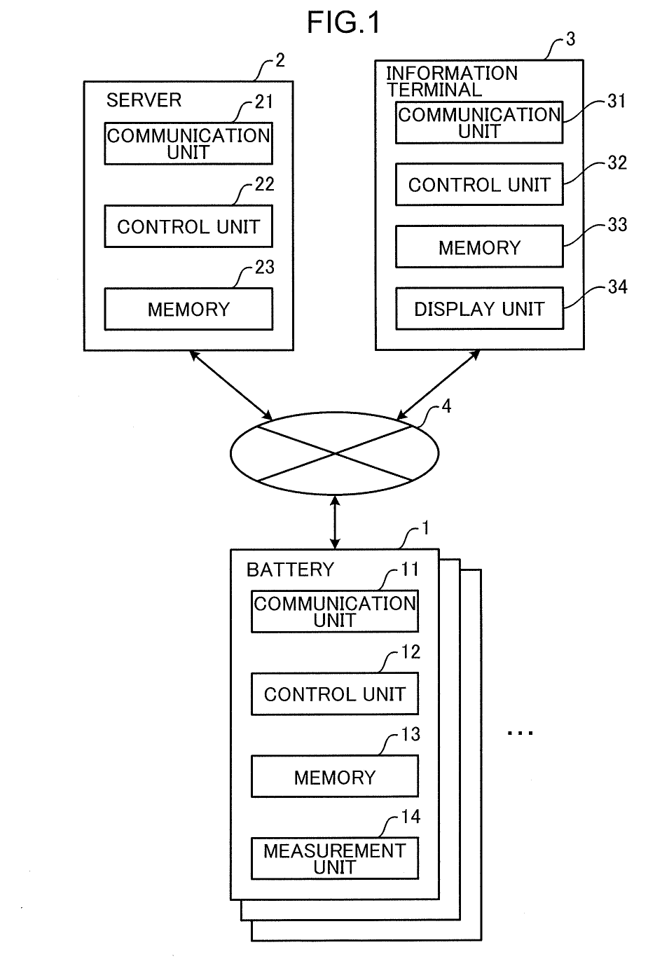

FIG. 1 is a diagram illustrating an overall configuration of a battery management system in a first embodiment of the present disclosure.

The battery management system illustrated in FIG. 1 includes a plurality of batteries 1, a server 2, and an information terminal 3. The server 2 is an example of an information processing device.

Each of the batteries 1 includes a plurality of secondary batteries, and stores electric power by charging, and supplies electric power by discharging. The secondary battery is, for example, a lead acid battery or a lithium ion battery. The battery 1 is a battery pack including a plurality of battery cells. The battery 1 is mounted as a power source on various devices. The battery 1 is mounted on an electric mobile body such as an electric vehicle, for example.

The battery 1 includes a communication unit 11, a control unit 12, a memory 13, and a measurement unit 14.

The measurement unit 14 includes, for example, sensors such as a current sensor, a voltage sensor, and a temperature sensor, and a processor that processes measurement data measured by these sensors. The measurement unit 14 measures a plurality of state items of the battery 1. The measurement unit 14 measures the plurality of state items such as a field effect transistor (FET) temperature, a cell temperature, a pack temperature, an ambient temperature, a cell current, a cell voltage, a pack current, a pack voltage, a pack resistance, the number of times of charging, a cumulative charge amount, a cumulative discharge amount, a full charge amount, and a state of charge (SOC). The measurement unit 14 stores measured values of the plurality of state items in the memory 13. The plurality of state items are not limited to the above items, and may be simply a battery temperature, a battery current, or a battery voltage, or may be a use time of the battery 1, a travel distance of the electric mobile body on which the battery 1 is mounted, or the like.

The memory 13 includes, for example, a storage device, such as a random access memory (RAM), a solid state drive (SSD), or a flash memory, capable of storing various types of information. The memory 13 stores history information of the plurality of state items measured by the measurement unit 14.

The control unit 12 includes, for example, a processor such as a central processing unit (CPU) or the like. The control unit 12 reads the history information of the plurality of state items from the memory 13, and generates battery log information including a battery ID for identifying the battery 1 and the read history information of the plurality of state items. The control unit 12 outputs the generated battery log information to the communication unit 11.

The communication unit 11 includes a communication device that connects the battery 1 to a network 4. The communication unit 11 transmits the battery log information of the battery 1 to the server 2. The battery log information includes a battery ID of the battery 1 and the history information of the plurality of state items of the battery 1. The communication unit 11 periodically transmits the battery log information to the server 2. For example, the communication unit 11 may transmit the battery log information including the history information of the plurality of state items measured for one minute to the server 2 every one minute.

Although the battery 1 includes the communication unit 11, the control unit 12, the memory 13, and the measurement unit 14 in the present embodiment, the present disclosure is not limited to this configuration, and a device on which the battery 1 is mounted may include the communication unit 11, the control unit 12, the memory 13, and the measurement unit 14.

The server 2 is communicably connected to the plurality of batteries 1 and the information terminal 3 via a network 4. The network 4 is the Internet, for example.

The server 2 includes a communication unit 21, a control unit 22, and a memory 23.

The communication unit 21 includes a communication device that connects the battery 1 to a network 4. The communication unit 21 receives the battery log information transmitted by the battery 1.

The memory 23 is a storage device, such as a random access memory (RAM), a solid state drive (SSD), a hard disk drive (HDD), or a flash memory, capable of storing various types of information. The memory 23 stores the battery log information. The memory 23 stores the history information of the plurality of state items in association with the battery ID. The memory 23 stores the history information of the plurality of state items of each of the plurality of batteries 1.

The memory 23 stores a relevant state item table in which each of a plurality of abnormal state items indicating the state item in which an abnormal value is detected and a relevant state item indicating the state item related to the abnormal state item are associated in advance. The abnormal value indicates a value exceeding a threshold. The threshold varies depending on the state item.

The communication unit 21 includes a communication device that connects the server 2 to the network 4. The communication unit 21 transmits display data of first and second dashboard screens described later to the information terminal 3.

The communication unit 21 receives a selection instruction transmitted by the information terminal 3. The selection instruction indicates one abnormal state item of one battery selected by the user via a first dashboard screen 40.

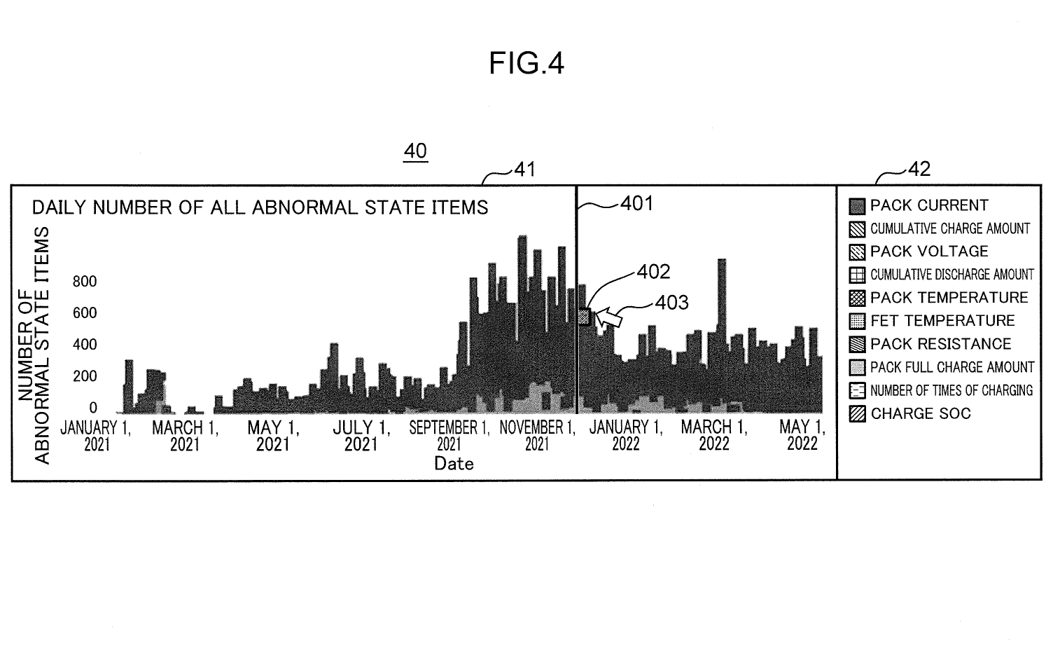

The control unit 22 includes, for example, a processor such as a CPU. The control unit 22 stores the battery log information received by the communication unit 21 in the memory 23. The control unit 22 generates display data for displaying the first dashboard screen 40 (see FIG. 4) that displays the plurality of abnormal state items of the plurality of batteries 1 in time series for each of the plurality of batteries 1, and transmits the generated display data to the information terminal 3 using the communication unit 21. As a result, the first dashboard screen 40 is displayed on a display unit 34 of the information terminal 3.

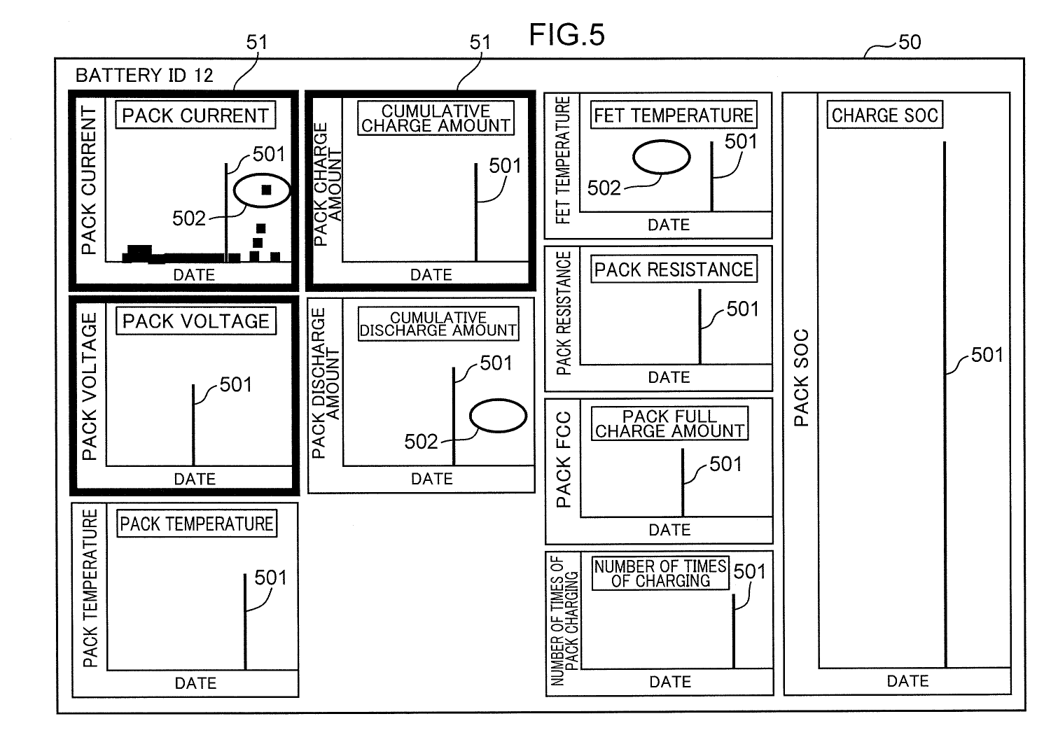

When detecting the selection of one abnormal state item among the plurality of abnormal state items, the control unit 22 generates display data for displaying a second dashboard screen 50 (see FIG. 5) that displays the plurality of state items of the battery 1 in which the abnormality indicated by the one abnormal state item has occurred, and transmits the generated display data to the information terminal 3 using the communication unit 21. As a result, the second dashboard screen 50 is displayed on the display unit 34 of the information terminal 3. The control unit 22 detects the selection of one abnormal state item by acquiring the selection instruction received by the communication unit 21.

The control unit 22 causes the second dashboard screen 50 to display a plurality of pieces of history information corresponding to the plurality of state items in the first period before and after the abnormality occurrence time point at which the abnormality indicated by the one abnormal state item has occurred. Here, the plurality of state items displayed on the second dashboard screen 50 includes not only relevant state items related to one abnormal state item but also state items not related to one abnormal state item.

The control unit 22 displays a reference index 401 (see FIG. 4) indicating an abnormality occurrence time point on the first dashboard screen 40.

The control unit 22 displays a reference index 501 (see FIG. 5) indicating an abnormality occurrence time point in each of the plurality of pieces of history information on the second dashboard screen 50.

The control unit 22 specifies an abnormal value included in each of the plurality of pieces of history information based on the plurality of pieces of history information corresponding to the plurality of state items, and sets the first period of the plurality of pieces of history information so that the specified abnormal value is included. Here, the first period is a period that defines a display range of the time axis of the plurality of pieces of history information. The first period may have a different length or the same length for each of the plurality of pieces of history information.

The information terminal 3 includes, for example, a portable information terminal such as a smartphone and a tablet computer, or a stationary information terminal such as a desktop computer. The information terminal 3 is used by a user who manages the plurality of batteries 1.

The information terminal 3 includes a communication unit 31, a control unit 32, a memory 33, and a display unit 34.

The communication unit 31 includes a communication device that connects the information terminal 3 to the network 4. The communication unit 31 receives the display data of each of the first dashboard screen 40 and the second dashboard screen 50 transmitted by the server 2. The communication unit 31 transmits the selection instruction to the server 2.

The control unit 32 includes, for example, a processor such as a CPU. The control unit 32 displays the first dashboard screen 40 on the display unit 34 by using the display data received by the communication unit 31, and displays the second dashboard screen 50 on the display unit 34 by using the display data.

The display unit 34 includes, for example, a display device such as a touch panel. The display unit 34 receives, on the first dashboard screen 40, a user's selection instruction to select one abnormal state item of one battery.

The memory 33 includes, for example, a storage device that can store various types of information, such as a RAM, an SSD, an HDD, or a flash memory.

Although the battery management system in the present embodiment includes the plurality of batteries 1, the server 2, and the information terminal 3, the present disclosure is not limited to this configuration, and the battery management system may include the plurality of batteries 1 and the information terminal 3 without including the server 2. In this case, the information terminal 3 has a function of the server 2.

Next, an operation of the battery management system in the first embodiment will be described.

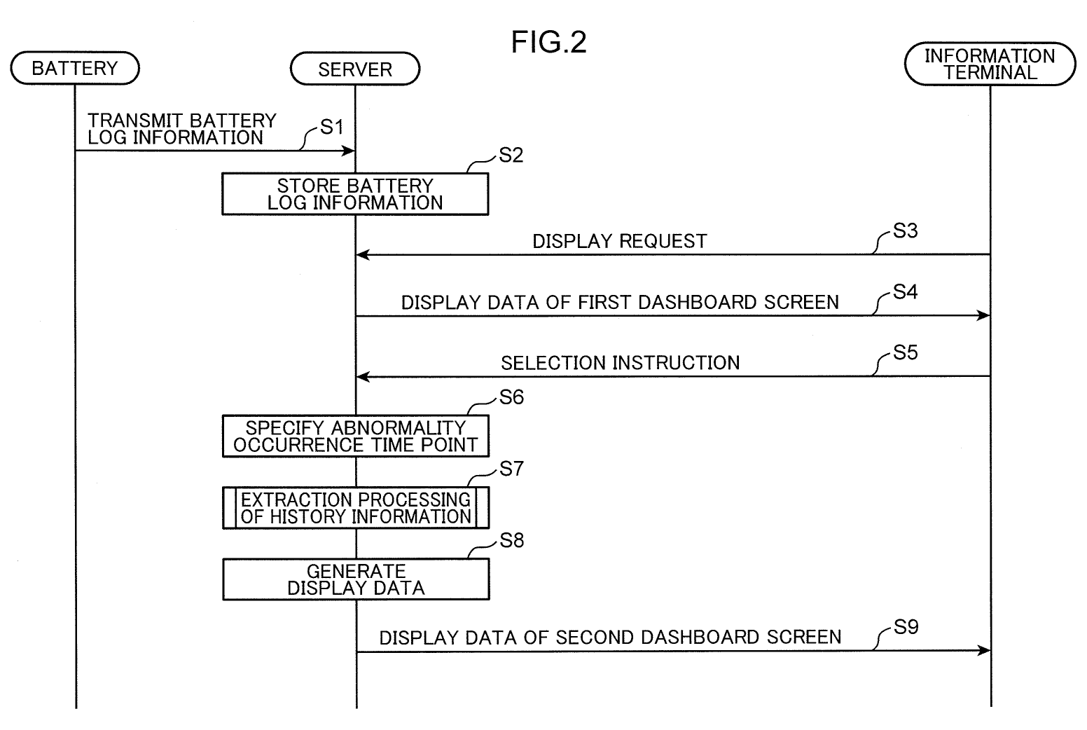

FIG. 2 is a sequence illustrating the battery management system in the first embodiment of the present disclosure.

First, in step S1, the control unit 12 of the battery 1 generates battery log information including the battery ID and history information of a plurality of state items, and transmits the generated battery log information to the server 2 using the communication unit 11. The battery management system includes a plurality of batteries 1. Therefore, each of the plurality of batteries 1 transmits the battery log information to the server 2.

Next, in step S2, the control unit 22 of the server 2 acquires the battery log information transmitted by the battery 1 using the communication unit 21, and stores the acquired battery log information in the memory 23. The control unit 22 stores the battery log information of the plurality of batteries 1 in the memory 23. The processing in steps S1 and S2 is periodically and repeatedly performed.

Next, in step S3, the control unit 32 of the information terminal 3 transmits a display request for the first dashboard screen 40 to the server 2 using the communication unit 31. This display request is transmitted according to a display instruction input by the user using the display unit 34.

Next, in step S4, the control unit 22 extracts, from the battery log information stored in the memory 23, a plurality of abnormal state items in which an abnormal value is detected, generates display data of the first dashboard screen 40 using the plurality of extracted abnormal state items, and transmits the generated display data to the information terminal 3 using the communication unit 21. As a result, the first dashboard screen 40 is displayed on the display unit 34 of the information terminal 3. Since the battery ID is associated with each of the plurality of abnormal state items, it is possible to identify which battery the abnormal state item belongs to.

The display range of the time axis included in the first dashboard screen 40 can be arbitrarily set by the user. For example, in a case where an error has occurred in December, there is a high possibility that the data of March is unnecessary. In this case, the control unit 22 may extract a plurality of abnormal state items from the battery log information of the latest October to December, and generate the display data of the first dashboard screen 40 from the plurality of extracted abnormal state items.

Next, in step S5, the control unit 32 acquires, on the first dashboard screen 40, a selection instruction for designating one abnormal state item of one battery selected by the user using the display unit 34, and transmits the acquired selection instruction to the server 2 using the communication unit 21.

Next, in step S6, the control unit 22 of the server 2 specifies an abnormality occurrence time point from the selection instruction acquired in step S5. Since the selection instruction includes the time point information indicating the abnormality occurrence time point, the control unit 22 may specify the abnormality occurrence time point from the time point information.

Next, in step S7, the control unit 22 of the server 2 executes extraction processing of the history information. Details of this processing will be described later.

Next, in step S8, the control unit 22 of the server 2 generates display data of the second dashboard screen 50 from the history information extracted in step S7.

Next, in step S9, the control unit 22 of the server 2 transmits the generated display data to the information terminal 3 using the communication unit 21.

FIG. 4 is a diagram illustrating an example of the first dashboard screen 40.

The first dashboard screen 40 includes a graph display column 41 and a legend display column 42. The graph display column 41 displays a bar graph showing the number of abnormal state items that have occurred in a predetermined period in time series. In the graph display column 41, the vertical axis represents the number of abnormal state items, and the horizontal axis is the time axis.

For example, the abnormal state item includes a pack current, a cumulative charge amount, a pack voltage, a cumulative discharge amount, a pack temperature, an FET temperature, a pack resistance, a pack full charge amount, the number of times of charging, and a charge SOC. For example, the color corresponding to the pack current is blue, the color corresponding to the cumulative charge amount is red, the color corresponding to the pack voltage is green, and the color corresponding to the cumulative discharge amount is yellow. As described above, the color is associated with the abnormal state item in advance. The bar graph is configured by stacking color blocks 402. In one color block 402, one battery, one abnormal state item, and a time point are associated with each other. The color block 402 is color-coded according to the abnormal state item.

For example, it is assumed that an abnormality has occurred m times in n batteries for one certain abnormal state item at a certain time point on the horizontal axis. In this case, blocks of n×m colors having colors corresponding to one abnormal state item are stacked in the bin corresponding to this time point.

The legend display column 42 displays a legend for explaining the color corresponding to the abnormal state item. For example, “0” is displayed in the first legend displayed in the legend display column 42. This indicates that the total number of abnormal state items corresponding to this legend is 0 in the predetermined period.

The bar graph can be selected in units of the color blocks 402. For example, the user moves a pointer 403 on a screen by operating a mouse (not illustrated) and clicks a position of interest on a bar graph. Alternatively, for example, in a case where the display unit 34 is a touch panel, the user touches a desired position on the bar graph. When the desired position of the bar graph is selected, one abnormal state item of one battery corresponding to the color block 402 displayed at the position is selected.

When the selection instruction of the color block 402 by the user is received, the display unit 34 displays the reference index 401 indicating the abnormality occurrence time point corresponding to the color block 402. The reference index 401 is a display object indicating an abnormality occurrence time point of one abnormal state item selected by the user. In this example, the reference index 401 is formed of a straight line parallel to the vertical axis. The reference index 401 may be highlighted using a color different from that of the bar graph. The display unit 34 may highlight the selected color block 402 by displaying a frame body surrounding the outer frame of the selected color block 402. In this way, by displaying the reference index 401, the user can easily confirm the abnormality occurrence time point.

FIG. 5 is a diagram illustrating an example of the second dashboard screen 50.

The second dashboard screen 50 includes a plurality of history information display columns 51. The history information display column 51 displays a graph indicating history information of the state item of one battery corresponding to the color block 402 selected on the first dashboard screen 40 in time series. In FIG. 5, since the battery 1 with battery ID “12” is selected as one battery, the second dashboard screen 50 displays the battery ID “12” in the upper part. In FIG. 5, for convenience of explanation, a graph showing history information is displayed only for the pack current, and illustration of a graph of history information is omitted for other state items. In the history information display column 51, the vertical axis represents a value of history information corresponding to each state item, and the horizontal axis is a time axis. Hereinafter, the value of the history information is referred to as a state value.

In FIG. 5, the second dashboard screen 50 includes ten history information display columns 51 corresponding to ten state items corresponding to the pack current, the pack voltage, the pack temperature, the cumulative charge amount, the cumulative discharge amount, the FET temperature, the pack resistance, the pack full charge amount, the number of times of charging, and the charge SOC. However, this is an example, and the second dashboard screen 50 may have history information of state items other than the ten state items. In addition, the number of state items displayed on the second dashboard screen 50 is not limited to 10, and an appropriate number other than 10 may be adopted.

The history information display column 51 displays the reference index 501. The reference index 501 indicates an abnormality occurrence time point of one abnormality occurrence item corresponding to the color block 402 selected on the first dashboard screen 40. That is, the reference index 501 represents the same time point as the reference index 401. Similarly to the reference index 401, the reference index 501 is a straight line indicating an abnormality occurrence time point, and is parallel to the vertical axis of the history information display column 51. The reference index 501 may be highlighted using a color different from the graph of the history information.

The display range of the time axis displayed in the history information display column 51 is the first period before and after the abnormality occurrence time point. Here, the acquisition frequency of the history information may be different depending on the state item. Therefore, in the example of FIG. 5, the first period is a period different according to the state item so that the variation is leveled in the data amount. However, this is an example, and the first period may be the same in all the history information display columns 51.

In this manner, by displaying the reference index 501, the user can easily confirm the abnormality occurrence time point corresponding to the color block 402 selected on the first dashboard screen 40 in each history information display column 51. In particular, in a case where the first period differs depending on the state item, the reference index 501 serves as a mark useful for confirming the abnormality occurrence time point.

The history information display column 51 may display the first period such that an abnormal value included in the history information is included. In this case, the history information display column 51 may highlight the abnormal value using the highlighted object 502. In this example, the highlighted object 502 is composed of an ellipse or a circle surrounding the abnormal value. As a result, the user can easily confirm which state item has an abnormal value in the first period, and can easily analyze one abnormal state item.

The second dashboard screen 50 may highlight the relevant state item related to the one abnormal state item in the history information display column 51. In the example of FIG. 5, the relevant state item is highlighted by surrounding the history information display column 51 corresponding to the relevant state item with a color different from the other history information display columns 51. Here, since the pack current, the pack voltage, and the cumulative charge amount are relevant state items, the history information display column 51 corresponding thereto is highlighted. As an aspect of highlighting the relevant state item, an aspect of displaying the relevant state item with a frame thicker than the frames of the other history information display columns 51 may be adopted instead of/in addition to changing the color of the frame.

As an aspect of highlighting the relevant state item, for example, an aspect of displaying the history information display column 51 of the relevant state item higher in display order than the history information display columns 51 of the other state items may be adopted. As the display order, for example, an order can be adopted in which the display order becomes higher as it goes to the left side and to the upper side. Alternatively, as the aspect of highlighting the relevant state item, an aspect may be adopted in which the size of the history information display column 51 corresponding to the relevant state item is larger than that of the history information display columns 51 corresponding to the other state items.

The second dashboard screen 50 may display only the history information of the relevant state item. The luminance of the second dashboard screen 50 may be higher in the history information display column 51 of the relevant state item than in the history information display columns 51 of the other state items. The second dashboard screen 50 may display the history information display column 51 of one abnormal state item selected on the first dashboard screen 40 among the relevant state items in an aspect different from the history information of other relevant state items. As a result, the user can easily confirm which state item has been selected.

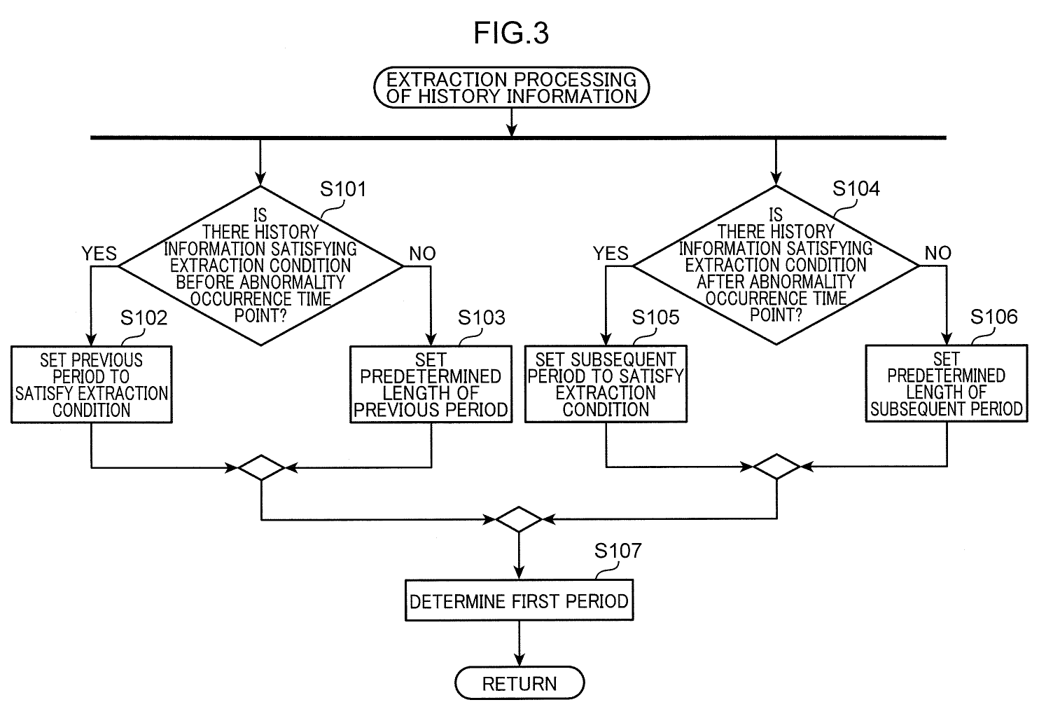

FIG. 3 is a flowchart illustrating details of extraction processing of the history information described in step S7 in FIG. 2. In FIG. 3, steps S101 to S103 are processing of setting a previous period of the first period, steps S104 to S106 are processing of setting a subsequent period of the first period, and both processes are performed in parallel.

First, processing of setting a previous period of the first period will be described. In step S101, the control unit 22 of the server 2 refers to the battery log information stored in the memory 23 to determine whether there is history information satisfying an extraction condition before the abnormality occurrence time point. Here, as the extraction condition, for example, a condition that history information including at least one abnormal value exists in at least one state item can be adopted. For example, the control unit 22 searches for an abnormal value for each of the plurality of state items from the battery log information acquired in the past from the abnormality occurrence time point. Then, in a case where the abnormal value can be searched, the control unit 22 determines YES in step S101. On the other hand, when the abnormal value cannot be searched for in all the state items, the control unit 22 determines NO in step S101.

For example, the control unit 22 calculates an average value μ and a standard deviation σ of the history information for each state item, and if there is a state value having a value separated from the average value μ by 2σ or more in the past from the abnormality occurrence time point, the state value may be specified as an abnormal value. Here, the selection criterion of the abnormal value is 2σ, but this is an example, and appropriate values such as 1σ and 3σ can be adopted.

Next, in step S102, the control unit 22 sets the previous period so as to satisfy the extraction condition. For example, the control unit 22 may set a period from a time point backward by a predetermined margin period from the acquisition time point of the searched abnormal value to the abnormality occurrence time point as a previous period of the first period.

If the previous period is shorter than the allowable upper limit period, the control unit 22 may further search the past for an abnormal value. If there is an abnormal value, the control unit 22 may set, as the previous period of the first period, a period from a time point backward by a predetermined margin period from the time point of acquisition of the abnormal value to the abnormality occurrence time point. That is, the control unit 22 may extend the previous period toward the past under the constraint that the previous period is equal to or less than the allowable upper limit period. As a result, the control unit 22 can include a plurality of abnormal values in the previous period.

Here, in a case where the previous period is different in the plurality of state items, the control unit 22 may adopt these previous periods as they are, or may specify one previous period from among the plurality of previous periods and align the remaining previous periods with the specified one previous period. In addition, the control unit 22 may set the previous period to the same length as the one previous period for the state item for which an abnormal value has not been searched. For example, the control unit 22 may specify the previous period of one abnormal state item selected by the user as the one previous period.

Next, in step S103, the control unit 22 sets the previous period of all the state items to a predetermined length of the previous period. For example, a value predetermined by the user or the battery management system can be adopted as the predetermined length of the previous period.

Next, processing of setting a subsequent period of the first period will be described. In step S104, the control unit 22 refers to the battery log information stored in the memory 23 to determine whether there is history information satisfying the extraction condition after the abnormality occurrence time point. This extraction condition is the extraction condition described in step S101. In a case where at least one abnormal value can be searched for in at least one state item in the future from the abnormality occurrence time point, the control unit 22 determines YES in step S104. On the other hand, in a case where the abnormal value cannot be searched for in all the state items in the future from the abnormality occurrence time point, the control unit 22 determines NO in step S104.

Next, in step S105, the control unit 22 sets the subsequent period so as to satisfy the extraction condition. For example, the control unit 22 may set a period from a future time point to an abnormality occurrence time point by a predetermined margin period from the searched abnormal value acquisition time point as the subsequent period of the first period. Note that, as in step S102, the control unit 22 may extend the subsequent period toward the future under the constraint that the subsequent period is equal to or less than the allowable upper limit period. Furthermore, in a case where the subsequent period is different in a plurality of state items, the control unit 22 may set the subsequent period of each state item using the same method as the previous period.

Next, in step S106, the control unit 22 sets the subsequent period of all the state items as a predetermined length of a subsequent period. For the predetermined length of the subsequent period, for example, a value predetermined by the user or the battery management system can be adopted.

Next, in step S107, the control unit 22 sets a period including the previous period and the subsequent period as a first period. As a result, as illustrated in FIG. 5, the display range of the time axis is set to the display range including the abnormality occurrence time point in all the history information display columns 51. When the processing of step S107 ends, the process proceeds to step S8 of FIG. 2.

As described above, according to the first embodiment, when the color block 402 is selected from the bar graph displayed on the first dashboard screen 40, the history information display column 51 indicating the history information corresponding to the plurality of state items of one battery corresponding to the color block 402 is displayed. The display ranges of the time axes of all the history information display columns 51 are set to the first period before and after the abnormality occurrence time point. As a result, the user can analyze the cause of the abnormality of the battery 1 in detail while checking the plurality of pieces of history information including the abnormality occurrence time point. Therefore, the burden on the user when analyzing the cause of the abnormality of the battery in detail is reduced.

### Second embodiment

In a second embodiment, the first period defining the display range of the time axis of the history information display column 51 is set to one battery use period (an example of the first use period). In the present embodiment, the same constituent elements as those in the first embodiment are denoted by the same reference numerals, and description thereof will be omitted. In the present embodiment, FIG. 1, FIG. 2, and FIG. 3 are used as a block diagram, a sequence diagram, and a flowchart, respectively.

Refer to FIG. 3. In the second embodiment, as the extraction conditions shown in steps S101 and S104, a condition that history information within the use period exists for one selected battery is adopted.

In step S101, the control unit 22 determines whether the use start time point of one battery can be specified from the battery log information before the abnormality occurrence time point. When the use start time point of the one battery can be specified (YES in step S101), the process proceeds to step S102. Here, the control unit 22 may specify, for example, the use start time point from the history information of the pack current. In specifying the use period of the battery, a state item different from the pack current may be adopted. For example, the use period may be specified from the pack voltage or the pack temperature.

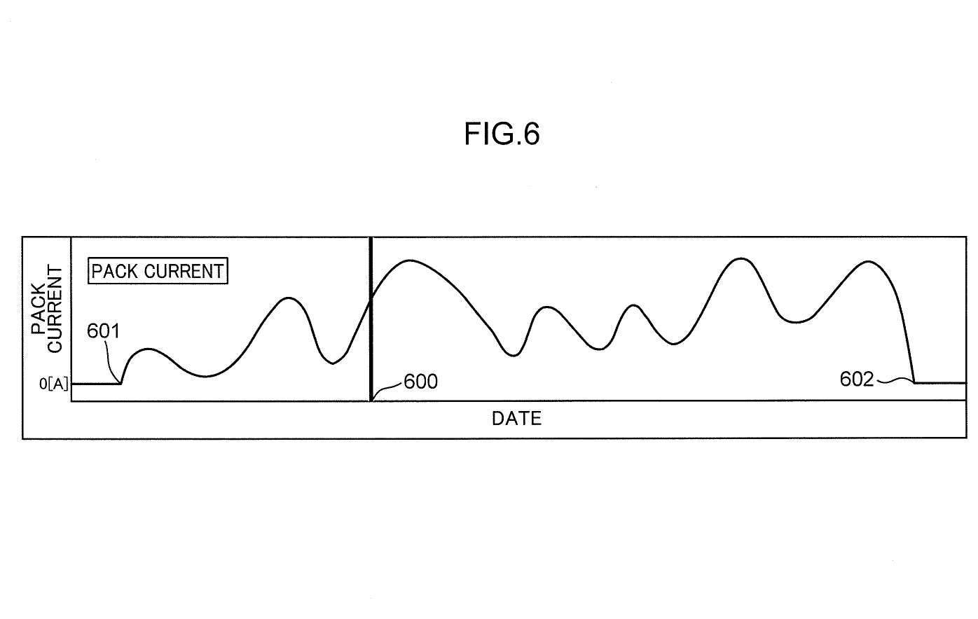

FIG. 6 is a graph illustrating a temporal transition of the history information of the pack current. In FIG. 6, the vertical axis represents the value of the pack current, and the horizontal axis is the time axis. The control unit 22 specifies, as a use start time point 601, a time point at which the value of the pack current first becomes 0 backward from an abnormality occurrence time point 600.

On the other hand, when the use start time point 601 cannot be specified from the battery log information (NO in step S101), the control unit 22 advances the process to step S103. The case where the use start time point 601 cannot be specified corresponds to, for example, a case where the server 2 has not been able to acquire the history information of the pack current of one battery for a certain period backward from the abnormality occurrence time point 600 due to a communication failure or the like.

In step S102, the control unit 22 sets a period from the use start time point 601 to the abnormality occurrence time point 600 as a previous period of the first period. In this case, the control unit 22 may set the previous period set from the history information of the pack current as the previous period of the history information of all the state items.

The processing of step S103 is the same as that in the first embodiment.

In step S104, after the abnormality occurrence time point 600, the control unit 22 determines whether the use end time point of one battery can be specified from the battery log information. When the use end time point of one battery can be specified (YES in step S104), the process proceeds to step S105. Here, the control unit 22 may specify, for example, the use start time point from the history information of the pack current. Referring to FIG. 6, the control unit 22 specifies, as a use end time point 602, a time point at which the value of the pack current first becomes 0 in the future from the abnormality occurrence time point 600.

On the other hand, when the use end time point 602 cannot be specified from the battery log information (NO in step S101), the control unit 22 advances the process to step S106. The case where the use end time point 602 cannot be specified corresponds to, for example, a case where the server 2 cannot acquire the history information of the pack current of one battery for a certain period from the abnormality occurrence time point 600 toward the future due to a communication failure or the like.

In step S105, the control unit 22 sets a period from the abnormality occurrence time point 600 to the use end time point 602 as a subsequent period of the first period. In this case, the control unit 22 may set the subsequent period, which has been set from the pack current, as the subsequent period of the history information of all the state items.

The processing of step S106 is the same as that in the first embodiment.

The processing of step S107 is the same as that in the first embodiment.

As described above, according to the second embodiment, the history information can be displayed on the second dashboard screen 50 while omitting a period that is not so important in analyzing the cause of the abnormality of the battery.

### Third embodiment

In a third embodiment, a plurality of use periods described in the second embodiment are displayed. The plurality of displayed use periods is an example of the second use period. In the present embodiment, the same constituent elements as those in the first and second embodiments are denoted by the same reference numerals, and description thereof will be omitted. In the present embodiment, FIG. 1 and FIG. 2 are used as a block diagram and a sequence diagram, respectively.

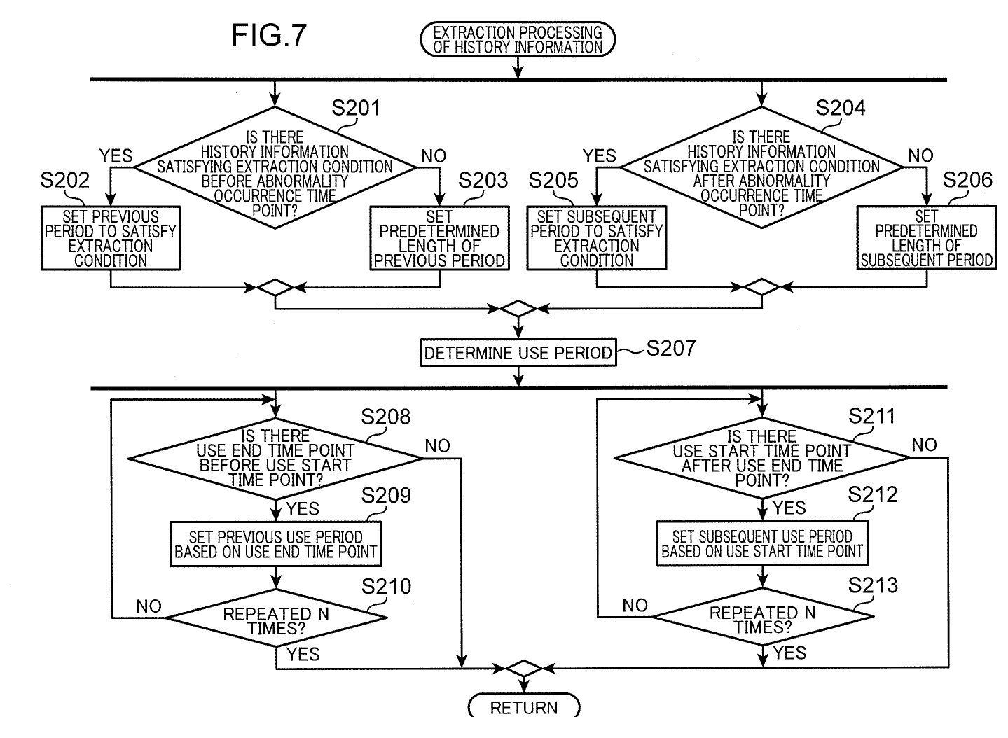

FIG. 7 is a flowchart illustrating details of extraction processing of history information according to the third embodiment. The processing of steps S201 to S207 is the same as the processing of steps S101 to S107 illustrated in FIG. 3. However, as the extraction conditions in steps S201 and S204, similarly to the second embodiment, a condition that history information within the use period exists for the selected one battery is adopted. In step S207, a use period is set instead of the first period.

Steps S208 to S210 are processing of setting a use period before the use period set in step S207. The processing of steps S211 to S213 is processing of setting a use period ahead of the use period set in step S207. Both processing are executed in parallel.

In step S208, the control unit 22 determines whether there is a use end time point 602' before the use start time point 601 of a use period set in step S207. When the use end time point 602' can be specified (YES in step S208), the control unit 22 sets the previous use period based on the use end time point 602' (step S209). Specifically, the control unit 22 specifies a time point at which the value of the pack current first becomes 0 before the use end time point 602' as the use start time point 601' of the previous use period. Then, the control unit 22 sets a period from the use start time point 601' to the use end time point 602' as a previous use period. In this case, the control unit 22 may set the previous use period set from the history information of the pack current as the previous use period of the history information of all the state items.

On the other hand, when the use end time point 602' cannot be specified (NO in step S208), the process proceeds to step S8 in FIG. 2. Here, the case where the use end time point 602' cannot be specified corresponds to, for example, a case where the server 2 cannot acquire the history information of the pack current of one battery for a certain period backward from the use start time point 601 due to a communication failure or the like.

In step S210, the control unit 22 determines whether the loop of steps S208 to S210 is repeated N times. When the loop of steps S208 to S210 is repeated N times (YES in step S210), the process proceeds to step S8 of FIG. 2. As a result, N use periods are set backward from the use period including the abnormality occurrence time point. On the other hand, when the loop of steps S208 to S210 is not repeated N times (NO in step S210), the process returns to step S208.

In step S211, the control unit 22 determines whether there is a use start time point 601'' after the use end time point 602 of the use period set in step S207. When the use start time point 601'' can be specified (YES in step S211), the control unit 22 sets a subsequent use period based on the use start time point 601'' (step S212). Specifically, the control unit 22 specifies a time point at which the value of the pack current first becomes 0 in the future from the use start time point 601'' as a use end time point 602'' of the subsequent use period. Then, the control unit 22 sets a period from the use start time point 601” to the use end time point 602” as a subsequent use period. In this case, the control unit 22 may set the subsequent use period set from the history information of the pack current as the subsequent use period of the history information of all the state items.

On the other hand, when the use start time point 601'' cannot be specified (NO in step S211), the process proceeds to step S8 in FIG. 2. Here, the case where the use start time point 601'' cannot be specified corresponds to, for example, a case where the server 2 cannot acquire the history information of the pack current of one battery for a certain period from the use end time point 602 toward the future due to a communication failure or the like.

In step S213, the control unit 22 determines whether the loop of steps S211 to S213 is repeated N times. When the loop of steps S211 to S213 is repeated N times (YES in step S213), the process proceeds to step S8 of FIG. 2. As a result, N use periods are set toward the future from the use period including the abnormality occurrence time point. On the other hand, when the loop of steps S211 to S213 is not repeated N times (NO in step S213), the process returns to step S211.

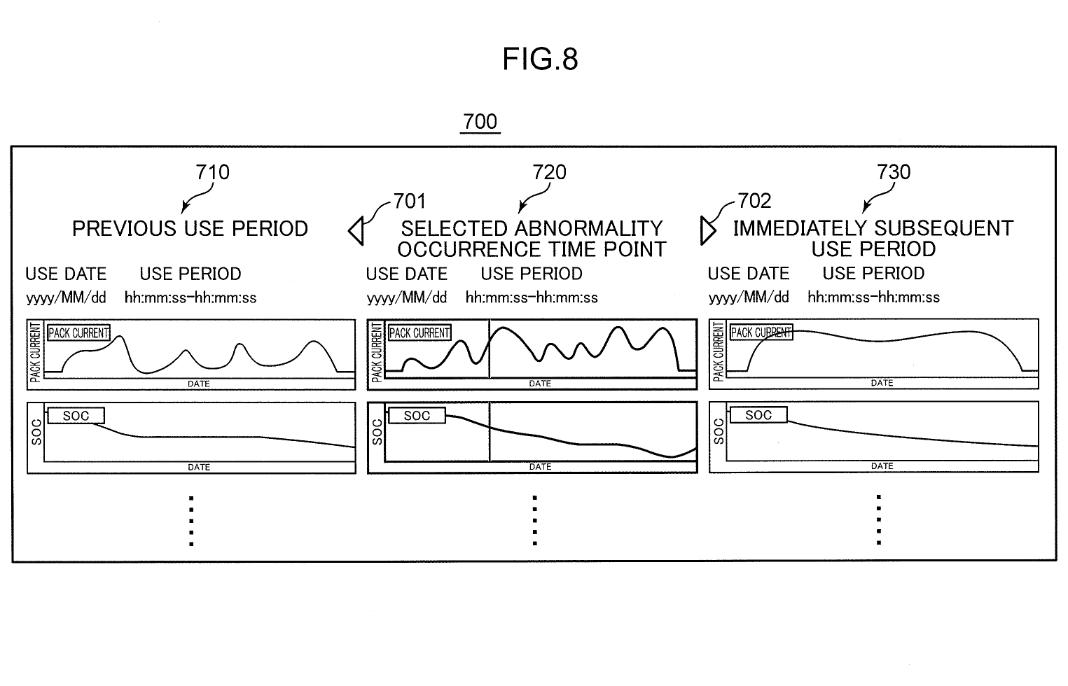

FIG. 8 is a diagram illustrating an example of a second dashboard screen 700 according to the third embodiment. The second dashboard screen 700 includes an immediately preceding display column 710, a center display column 720, and an immediately subsequent display column 730. The center display column 720 displays, by default, history information of each state item in a use period including an abnormality occurrence time point. Here, the center display column 720 displays the history information of the use period including the abnormality occurrence time point, and thus, displays the title of “selected abnormality occurrence time point”. In the center display column 720, history information of each state item is displayed in a vertical line.

The immediately preceding display column 710 displays history information of each state item of the use period immediately before the use period of the history information displayed by the center display column 720. Here, in the immediately preceding display column 710, history information of each state item is displayed in a vertical line.

The immediately subsequent display column 730 displays the history information of each state item in the use period immediately after the use period of the history information displayed in the center display column 720. Here, in the immediately subsequent display column 730, the history information of each state item is displayed in a vertical line.

In the immediately preceding display column 710, the center display column 720, and the immediately subsequent display column 730, history information having the same state item is displayed in the same row.

The immediately preceding display column 710, the center display column 720, and the immediately subsequent display column 730 respectively display a use date and a use period. The use date indicates the year/month/date of the use period. The use period indicates a use start time point and a use end time point.

In the example of FIG. 8, the center display column 720 is highlighted more than the immediately preceding display column 710 and the immediately subsequent display column 730. Examples of the highlight display include different colors and thickening lines and characters.

A return button 701 is provided at the boundary between the immediately preceding display column 710 and the center display column 720. When the selection instruction of the return button 701 is input by the user, the control unit 22 switches the history information currently displayed in each of the immediately preceding display column 710, the center display column 720, and the immediately subsequent display column 730 to the history information in the immediately preceding use period. As a result, history information in the use period two periods before the use period including the abnormality occurrence time point is displayed in the immediately preceding display column 710, history information in the use period one period before the use period including the abnormality occurrence time point is displayed in the center display column 720, and history information in the use period including the abnormality occurrence time point is displayed in the immediately subsequent display column 730.

Every time the selection instruction for the return button 701 is input once, the control unit 22 switches the history information currently displayed in each of the immediately preceding display column 710, the center display column 720, and the immediately subsequent display column 730 to the history information in the previous use period. Note that, in the flowchart of FIG. 7, since N use periods are set immediately before, the control unit 22 can display, for each of the immediately preceding display column 710, the center display column 720, and the immediately subsequent display column 730, the history information up to N-1 times backward from the use period of the history information displayed by default.

Similarly, a forward button 702 is provided at the boundary between the immediately subsequent display column 730 and the center display column 720. When the selection instruction of the forward button 702 is input by the user, the control unit 22 switches the history information currently displayed in each of the immediately preceding display column 710, the center display column 720, and the immediately subsequent display column 730 to the history information in the immediately subsequent use period. As a result, history information in the use period including the abnormality occurrence time point is displayed in the immediately preceding display column 710, history information in the use period one period after the use period including the abnormality occurrence time point is displayed in the center display column 720, and history information in the use period two periods after the use period including the abnormality occurrence time point is displayed in the immediately subsequent display column 730.

Every time the selection instruction for the forward button 702 is input once, the control unit 22 switches the history information currently displayed in each of the immediately preceding display column 710, the center display column 720, and the immediately subsequent display column 730 to the history information in the subsequent use period. Note that, in the flowchart of FIG. 7, since N use periods are set immediately thereafter, the control unit 22 can display, for each of the immediately preceding display column 710, the center display column 720, and the immediately subsequent display column 730, up to N-1 pieces of history information toward the future after the use period of the history information displayed by default.

As described above, according to the third embodiment, since the history information in the plurality of second use periods is displayed, the user can check the history information over a long period of time and can perform more accurate analysis.

### Fourth embodiment

In a fourth embodiment, in one battery corresponding to one abnormal state item, one cycle period of charging and discharging including an abnormality occurrence time point is set as a first period. In the present embodiment, the same constituent elements as those in the first to third embodiments are denoted by the same reference numerals, and description thereof will be omitted. In the present embodiment, FIG. 1, FIG. 2, and FIG. 3 are used as a block diagram, a sequence diagram, and a flowchart, respectively.

Refer to FIG. 3. In the present fourth embodiment, as the extraction conditions shown in steps S101 and S104, a condition that there is history information within one cycle period of charging and discharging for one selected battery is adopted. The one cycle period of charging and discharging refers to a period from the start of discharge to the end of charge.

In step S101, the control unit 22 determines whether the SOC (state of charge) decrease start time point of one battery can be specified from the history information of the SOC before the abnormality occurrence time point. When the SOC decrease start time point of one battery can be specified (YES in step S101), the process proceeds to step S102.

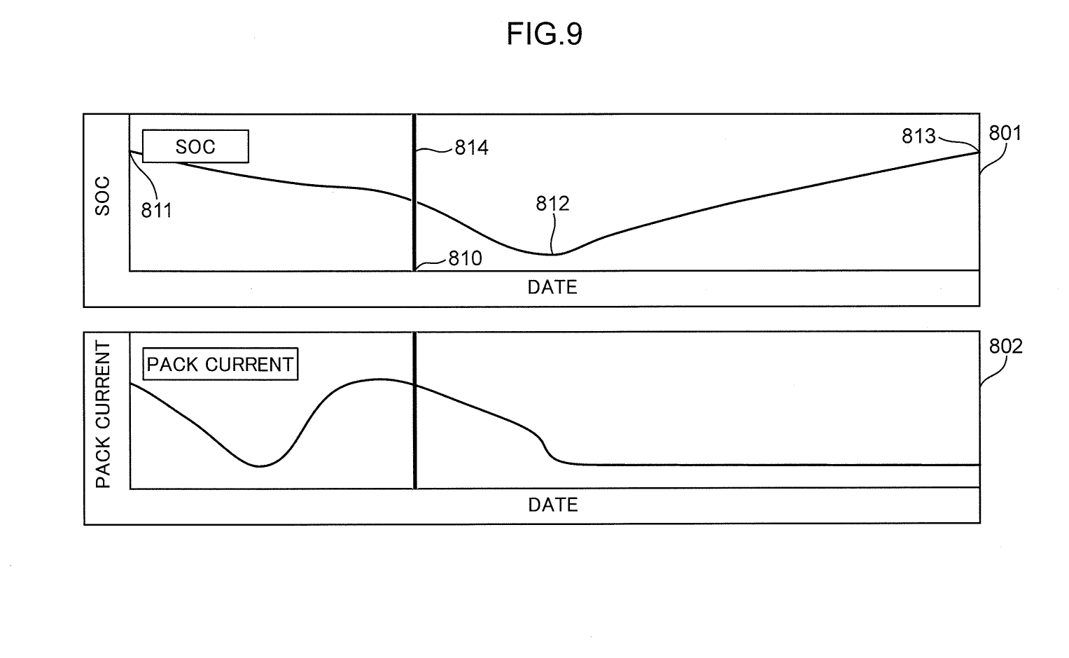

FIG. 9 is a graph showing a temporal transition of history information displayed on the second dashboard screen 50 in the fourth embodiment. FIG. 9 illustrates history information of the SOC and the pack current, and omits other history information. In FIG. 9, the vertical axis represents the SOC value, and the horizontal axis is the time axis. The control unit 22 specifies, as an SOC decrease start time point 811, a time point at which the SOC starts to decrease backward from an abnormality occurrence time point 810.

On the other hand, when the SOC decrease start time point 811 of one battery cannot be specified from the battery log information (NO in step S101), the control unit 22 advances the process to step S103. The case where the SOC decrease start time point 811 cannot be specified corresponds to, for example, a case where the server 2 cannot acquire the history information of the pack current of one battery for a certain period backward from the abnormality occurrence time point 810 due to a communication failure or the like.

In step S102, the control unit 22 sets a period from the SOC decrease start time point 811 to the abnormality occurrence time point 810 as a previous period of the first period. In this case, the control unit 22 may set the previous period set from the history information of the SOC as the previous period of the history information of all the state items.

The processing of step S103 is the same as that in the first embodiment.

In step S104, after the abnormality occurrence time point 810, the control unit 22 determines whether an SOC rise end time point of one battery can be specified from the history information of the SOC. When the SOC rise end time point of one battery can be specified (YES in step S104), the process proceeds to step S105. Referring to FIG. 9, the control unit 22 specifies a time point at which the increase in the SOC ends as an SOC rise end time point 813 in the future from the abnormality occurrence time point 810.

On the other hand, when the SOC rise end time point 813 of one battery cannot be specified from the battery log information (NO in step S104), the control unit 22 advances the process to step S106. The case where the SOC rise end time point 813 cannot be specified corresponds to, for example, a case where the server 2 cannot acquire the history information of the pack current of one battery for a certain period from the abnormality occurrence time point 810 toward the future due to a communication failure or the like.

In step S105, the control unit 22 sets a period from the abnormality occurrence time point 810 to the SOC rise end time point 813 as a subsequent period of the first period. In this case, the control unit 22 may set the subsequent period set from the history information of the SOC as the subsequent period of the history information of all the state items.

The processing of step S106 is the same as that in the first embodiment.

The processing of step S107 is the same as that in the first embodiment.

As illustrated in FIG. 9, similarly to the first embodiment, A reference index 814 indicating the abnormality occurrence time point 810 is displayed in the history information of each state item. When the reference index 814 is within the period from the SOC decrease start time point 811 to an SOC rise start time point 812, the user can grasp that an abnormality has occurred during discharging, that is, when a load is used. On the other hand, when the reference index 814 is within the period from the SOC rise start time point 812 to the SOC rise end time point 813, the user can grasp that an abnormality has occurred during charging. Further, for other state items such as the pack current, history information of one cycle period of charging and discharging is displayed, and moreover, the reference index 814 is displayed at the abnormality occurrence time point 810. Therefore, the user can easily confirm, with respect to the other state items, whether an abnormality has occurred during the use of the load or during the charging. As described above, according to the present embodiment, since the transition of the history information in one cycle period of charging and discharging can be confirmed, the cause of the abnormality of the battery can be more accurately analyzed.

### Fifth embodiment

In a fifth embodiment, the first history information and the second history information are aligned and displayed on the second dashboard screen. The first history information is history information of one abnormal state item in the first period. The second history information is history information of one abnormal state item in a second period different from the first period and having the same time width as the first period, in which the same abnormality as the abnormality indicated by one abnormal state item has occurred. Here, the first history information and the second history information include history information of a target battery which is one battery corresponding to one abnormal state item and history information of another battery which is a battery different from the one battery. Note that in the present embodiment, the same components as those in the first to fourth embodiments are denoted by the same reference numerals, and description thereof will be omitted. As the other battery, for example, the battery 1 in which the same abnormal state item as that of the target battery has occurred at the abnormality occurrence time point can be adopted.

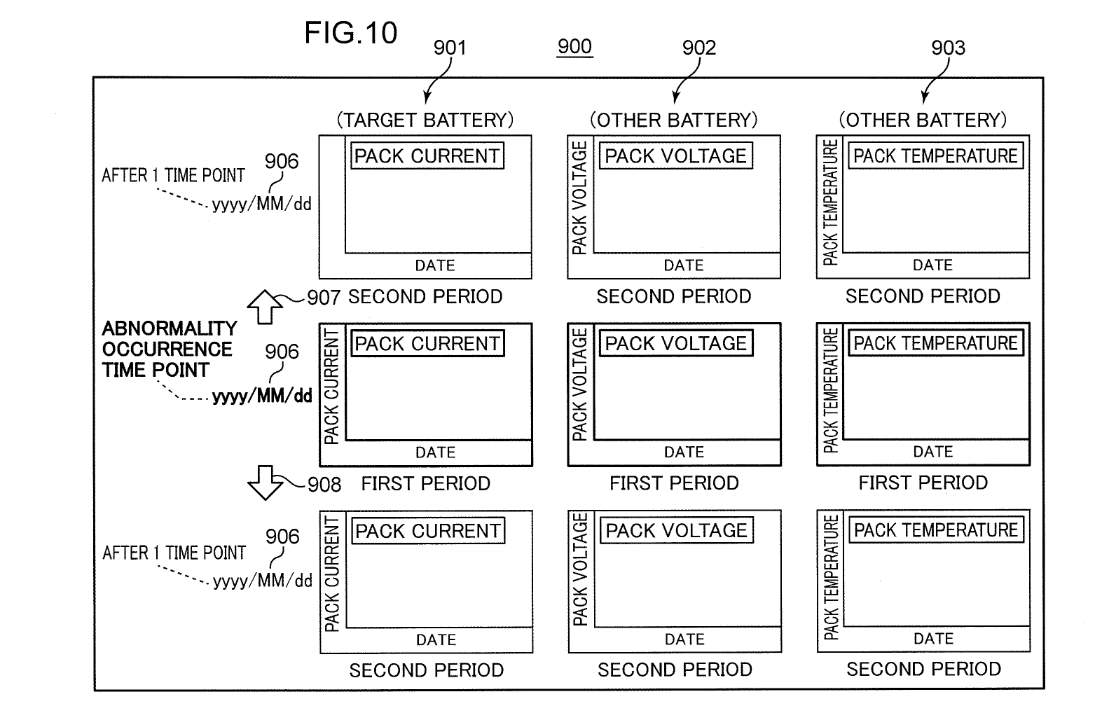

FIG. 10 is a diagram illustrating an example of a second dashboard screen 900 in the fifth embodiment. The second dashboard screen 900 includes a target battery display column 901 and other battery display columns 902 and 903.

The target battery display column 901 displays the first and second history information of the target battery in a vertical line in the order of the second, first, and second history information. The other battery display columns 902 and 903 display the first and second history information of each of the two other batteries in a vertical line in the order of the second, first, and second history information. In the example of FIG. 10, since two other batteries are set as display targets, the second dashboard screen 900 displays two columns of the other battery display columns 902 and 903. However, this is an example, and if there are three or more other batteries to be displayed, the second dashboard screen 50 may display three or more columns of other battery display columns.

On the second dashboard screen 900, the second history information in the second period in the most recent past with respect to the first period is displayed in the target battery and the two other batteries in the first row, the first history information in the first period is displayed in the target battery and the two other batteries in the second row, and the second history information in the second period in the most recent future with respect to the first period is displayed in the target battery and the two other batteries in the third row.

For example, it is assumed that one abnormal state item is a pack current. In this case, the control unit 22 specifies, from the history information of the pack current of the target battery, the occurrence time point of the abnormal value that has occurred in the past more than the first period and occurred most recently, and sets the second period based on the specified occurrence time point of the abnormal value. Here, the control unit 22 may set the length of the previous period of the second period to be the same as the length of the previous period of the first period, and set the length of the subsequent period of the second period to be the same as the length of the subsequent period of the first period.

Similarly, the control unit 22 specifies, from the state item of the pack current of the target battery, the occurrence time point of the abnormal value that has occurred in the future more than the first period and occurred most recently, and may set the second period based on the specified occurrence time point of the abnormal value.

Furthermore, the control unit 22 also sets the first period and the latest second periods in the past and the future for the other batteries.

Then, the control unit 22 may display the first history information in the first period and the second history information in the second period set in the target battery in the target battery display column 901. Similarly, the control unit 22 may display the first history information in the first period and the second history information in the second period set in the other batteries in the other battery display columns 902 and 903.

A year/month/date display column 906 is provided at the left end of each of the first to third rows, and the year/month/date of each of the first period and the second period is displayed.

A forward button 907 is provided between the first row and the second row. In addition, a return button 908 is provided between the second row and the third row. When the selection instruction of the forward button 907 is input by the user, the control unit 22 switches the second history information displayed in the first row to the second history information of the second period in the most recent future with respect to the second history information. At the same time, the control unit 22 switches the first history information displayed in the second row to the second history information in the second period in the most recent future with respect to the first history information. Further, the control unit 22 switches the second history information displayed in the third row to the first history information. That is, when the selection instruction of the forward button 907 is input, the history information displayed in each of the first to third rows is switched to the history information in the most recent future with respect to the currently displayed history information.

On the other hand, when the selection instruction of the return button 908 is input by the user, the control unit 22 switches the second history information displayed in the first row to the first history information. At the same time, the control unit 22 switches the first history information displayed in the second row to the second history information in the second period in the most recent past with respect to the first history information. Further, the control unit 22 switches the second history information displayed in the third row to the second history information in the most recent past with respect to the second history information. That is, when the selection instruction of the return button 908 is input, the history information displayed in each of the first to third rows is switched to the history information in the most recent past with respect to the history information currently displayed.

The control unit 22 specifies the occurrence time point of the abnormal value occurring in the most recent past described above, and repeats the processing of setting the second period with reference to the occurrence time point of the specified abnormal value N times backward. In addition, the control unit 22 may repeat the processing of specifying the occurrence time point of the abnormal value occurring in the most recent future and setting the second period based on the specified occurrence time point of the abnormal value N times toward the future.

In this case, by inputting the selection instruction of the return button 908, the user can display, on the second dashboard screen 900, the second history information of the second period up to N times backward with respect to the first period. Further, by inputting a selection instruction of the forward button 907, the user can display the second history information of the second period up to N times toward the future with respect to the first period on the second dashboard screen 900.

As described above, according to the present embodiment, since the first history information and the second history information in which the same abnormality as the abnormality indicated by the one abnormal state item has occurred are displayed, the user can confirm the pattern of the history information for this abnormality. In addition, since the first history information and the second history information have the same time width, and both pieces of history information are displayed side by side, comparison between both pieces of history information is facilitated.

In the present embodiment, the second dashboard screen 900 displays the history information in the abnormal state item, but may display the history information in the relevant state item.

Modifications described below can be adopted for the present disclosure.

### Modification

In the first embodiment, the control unit 22 sets the first period such that the abnormal value is included, but the present invention is not limited thereto, and one or a plurality of unit periods in which the occurrence frequency of the abnormal value exceeds the reference frequency may be set as the first period based on a plurality of pieces of history information corresponding to a plurality of state items. As an example of the unit period, an appropriate value such as 1 hour or 2 hours can be adopted. The occurrence frequency of the abnormal value is an example of an index of the abnormal value, and the reference frequency is an example of a threshold. The index of the abnormal value may be a statistical value of the abnormal value such as an average value of the abnormal values.

For example, the control unit 22 sets a unit period in the past starting from the abnormality occurrence time point for each of the plurality of state items, and determines whether the occurrence frequency of the abnormal value exceeds the reference frequency (for example, 3 times) in the set unit period. When the occurrence frequency of the abnormal value in this unit period exceeds the reference frequency, the control unit 22 further shifts the unit period in the past starting from this unit period, and determines whether the occurrence frequency of the abnormal value exceeds the reference frequency in the shifted unit period.

Under the constraint that such processing is repeated a predetermined upper limit number of times, the control unit 22 repeats such processing until a unit period in which the occurrence frequency of the abnormal value is lower than the reference frequency is detected. Similarly, the control unit 22 repeats from the abnormality occurrence time point to the future until the occurrence frequency of the abnormal value becomes lower than the reference frequency under the constraint that the predetermined upper limit number of times is repeated as in the past case. Then, the control unit 22 sets the end point of the unit period in which the occurrence frequency of the abnormal value falls below the reference frequency in the past as the start point of the first period, and sets the start point of the unit period in which the occurrence frequency of the abnormal value falls below the reference frequency in the future as the end point of the first period. In this case, the first period has a different length for each state item. However, this is an example, and the control unit 22 may set the first period of all the state items to the same length as the first period set for one abnormal item.

In this case, since the history information of the period in which the occurrence frequency of the abnormal value is high is displayed, the user can intensively analyze the period in which the sign of the abnormality appears.

The present disclosure is useful in the technical field of supporting such analysis because abnormality of a battery can be easily analyzed.

1. An information processing method in a computer, comprising:
acquiring, from battery log information of a plurality of batteries, state data of the plurality of batteries;
displaying, based on the state data, a plurality of abnormal state items of the plurality of batteries in time series for each battery; and
displaying a plurality of state items of a battery in which an abnormality indicated by one abnormal state item has occurred when selection of the one abnormal state item among the plurality of abnormal state items is detected, wherein
the displaying of the plurality of state items includes displaying a plurality of pieces of history information corresponding to the plurality of state items in a first period before and after an abnormality occurrence time point at which an abnormality indicated by the one abnormal state item has occurred.

2. The information processing method according to claim 1, wherein the displaying of the plurality of abnormal state items in time series for each battery includes displaying a reference index indicating the abnormality occurrence time point.

3. The information processing method according to claim 1, wherein the displaying of the plurality of state items includes displaying a reference index indicating the abnormality occurrence time point in each of the plurality of pieces of history information.

4. The information processing method according to claim 1, wherein
the displaying of the plurality of state items includes
specifying an abnormal value included in each of the plurality of pieces of history information based on the plurality of pieces of history information, and
setting the first period such that the abnormal value is included.

5. The information processing method according to claim 4, wherein the first period includes one or a plurality of unit periods in which an index of the abnormal value exceeds a threshold.

6. The information processing method according to claim 4, wherein
the displaying of the plurality of state items includes
specifying a state item related to the one abnormal state item among the plurality of state items, and
highlighting history information of a state item associated with the one abnormal state item.

7. The information processing method according to claim 4, wherein the displaying of the plurality of state items includes highlighting the abnormal value.

8. The information processing method according to claim 1, wherein
the displaying of the plurality of state items includes
specifying a first use period in which one battery is in a use state based on the plurality of pieces of history information of the one battery corresponding to the one abnormal state item, and
setting the first period as the first use period.

9. The information processing method according to claim 8, wherein the first use period includes a plurality of second use periods in the use state of the one battery.

10. The information processing method according to claim 1, wherein
the displaying of the plurality of state items includes
specifying, based on the plurality of pieces of history information of one battery corresponding to the one abnormal state item, one cycle period of charging and discharging of the one battery including the abnormality occurrence time point, and
setting the first period to the one cycle period.

11. The information processing method according to claim 1, wherein
the displaying of the plurality of state items includes
displaying first history information that is history information of the one abnormal state item in the first period, and
displaying second history information as history information of the one abnormal state item in a second period different from the first period in which a same abnormality as the abnormality indicated by the one abnormal state item has occurred, the second period having a same time width as the first period, in alignment with the first history information.

12. The information processing method according to claim 11, wherein the first history information and the second history information include history information of one battery corresponding to the one abnormal state item and history information of a battery different from the one battery.

13. An information processing device comprising a processor, wherein
the processor is configured to execute:
acquiring, from battery log information of a plurality of batteries, state data of the plurality of batteries;
displaying, based on the sate data, a plurality of abnormal state items of the plurality of batteries in time series for each battery; and
displaying a plurality of state items of a battery in which an abnormality indicated by one abnormal state item has occurred when selection of the one abnormal state item among the plurality of abnormal state items is detected, and
the displaying of the plurality of state items includes displaying a plurality of pieces of history information corresponding to the plurality of state items in a first period before and after an abnormality occurrence time point at which an abnormality indicated by the one abnormal state item has occurred.

14. A non-transitory computer readable recording medium storing an information processing program for causing a computer to execute:
acquiring, from battery log information of a plurality of batteries, state data of the plurality of batteries;
displaying, based on the state data, a plurality of abnormal state items of the plurality of batteries in time series for each battery; and
displaying a plurality of state items of a battery in which an abnormality indicated by one abnormal state item has occurred when selection of the one abnormal state item among the plurality of abnormal state items is detected, wherein
the displaying of the plurality of state items includes displaying a plurality of pieces of history information corresponding to the plurality of state items in a first period before and after an abnormality occurrence time point at which an abnormality indicated by the one abnormal state item has occurred.
